(19) United States
(12) Patent Application Publication
(10) Pub. No.: US 2013/0000967 A1
(43) Pub. Date: Jan. 3, 2013

(54) ELECTRIC JOINT STRUCTURE AND METHOD FOR PREPARING THE SAME

(75) Inventors: Dong Jun LEE, Gyeonggi-do (KR); Jung Suk Kim, Seoul (KR)

(73) Assignee: SAMSUNG ELECTRO-MECHANICS CO., LTD.

(21) Appl. No.: 13/536,465

(22) Filed: Jun. 28, 2012

(30) Foreign Application Priority Data
Jun. 28, 2011 (KR) 10-2011-0062947

(51) Int. Cl. H01R 4/02; B23K 1/20; H05K 1/11

(52) U.S. Cl. 174/261; 174/94 R; 228/203

(57) ABSTRACT

Disclosed herein are an electric joint structure including a joint, an intermetallic compound (IMC), and a solder layer, wherein the intermetallic compound (IMC) is generated from an electroless surface treatment plating layer including nickel plating coating of 1 μm or less, a method for preparing the same, and a printed circuit board including the same. The electric joint structure having the intermetallic compound structure according to the exemplary embodiment of the present invention can have a joint structure capable of improving impact resistance by suppressing the generation of a Ni—Sn based intermetallic compound and a P-enriched layer at a solder joint interface during a reflow process and improving workability including the Ni layer before the reflow process.

### CROSS REFERENCE(S) TO RELATED APPLICATIONS

This application claims the benefit under 35 U.S.C. Section 119 of Korean Patent Application Serial No. 10-2011-0062947, entitled “Electric Joint Structure, And Method For Preparing The Same” filed on Jun. 28, 2011, which is hereby incorporated by reference in its entirety into this application.

### BACKGROUND OF THE INVENTION

1. Technical Field The present invention relates to an electric joint structure, a method for preparing the same, and a printed circuit board.

2. Description of the Related Art

As a market of electronic products such as mobile phones, electronic devices, or the like, has been suddenly increased, the importance of portability of electronic products has been increased. Due to the portability, it is highly likely to drop products and apply an impact to products. Therefore, the electronic products needs impact resistance. The weakest portion against an impact is a solder interface that connects electronic devices.

Generally, an example of a method of connecting various devices such as a die and a main board may largely include a wire bonding method and a solder joint method. Among others, in the case of the solder joint method, the impact resistance at the solder interface is a very important factor.

Meanwhile, as electronic parts are highly integrated, a technology of treating a surface of a printed circuit board (PCB) is diversified. Recently, as a demand for thin and highly integrated PCB products is increased, the surface treatment technology has been changed from an electrolytic Ni/Au surface treatment technology to an electroless surface treatment technology capable of easily implementing tailless so as to implement process simplification, noise free, or the like.

In particular, when the surface treatment method is applied to electroless Ni/Au (hereinafter, referred to as ENIG) plating layers including Ni or Ni/Pd/Au (hereinafter, referred to as ENEPIG) plating layers, a breakage due to the impact occur at the ENIG and the ENEPIG that are the solder and the nickel plating layer. It has been known that the cause of weak impact resistance is a Ni₃SN₄ based intermetallic compound (IMC) and a P-enriched layer formed during a reflow process between the Ni layer and the solder.

In addition, various elements are included in the Ni coating layer. Among those, a concentration of phosphorus (P) is very important. In particular, when the concentration of phosphorus is high when the solder is joined, the P-enriched layer including a considerable amount of phosphorus is formed at an interface between the solder and the undercoat, thereby degrading reliability after the soldering. This is similarly applied even to Pd, such that the solder joint reliability in the coating may be degraded.

Next, FIG. 1 shows a shape in the case in which a surface-treated plating layer is interconnected to a copper joint using the electroless Ni/Au or Ni/Pd/Au of the related art by the solder joint method.

Referring to FIG. 1, the ENIG and the ENEPIG that the surface treatment plating layer (not shown) is formed on the copper joint 10 and the solder layer 20 for solder joining is disposed thereon. While the reflow process of the Ni plating layer and the solder layer 20 is performed, a Ni—P 30, a P-enriched layer 40, an Ni—Sn based 50 intermetallic compound are formed at the solder joint interface A. Due to the formation of the Ni—P 30, the P-enriched layer 40, the Ni—Sn based 50 intermetallic compound, a fracture surface that is easily broken at the solder joint interface A is easily generated, thereby degrading drop reliability.

The intermetallic compound and the P-enriched layer are generated due to the difference in a diffusion rate of metals included in the surface treatment plating layer and the solder layer during the reflow process. Therefore, nickel (Ni) and phosphorus (P) of the surface treatment plating layer and tin (Sn) of the solder layer, or the like, are diffused, thereby generating separate intermetallic compound and P-enriched layer between the plating layer and the solder layer.

When the surface treatment plating layer is the ENIG, the Ni is a thickness of 3 μm in minimum, the Au is a thickness of about 0.05 to 0.5 μm. When the surface treatment plating layer is the ENEPIG, the Ni is a thickness of 3 μm in minimum, the Pd is a thickness of about 0.05 to 0.3 μm, and the Au has a thickness of about 0.05 to 0.5 μm.

Meanwhile, FIG. 2 shows a shape in the case in which the plating layer surface-treated on the copper joint using a material (for example, Cu OSP, Immersion Sn, or the like) that does not include the Ni layer of the related art is interconnected with the metal by using the solder joint method.

Referring to FIG. 2, the surface treatment plating layer and the solder layer 20 for solder joining are disposed on the copper joint 10. In this case, a Cu—Sn based intermetallic compound 50 is generated. Analyzing the Cu—Sn based intermetallic compound in detail, the Cu—Sn based intermetallic compound is divided into two layers of Cu₆Sn₅ and Cu₃Sn. In this case, as the reflow process or the heat treatment process is increased, voids are generated at the Cu₃Sn layer, thereby degrading heat resistance and solderability.

### SUMMARY OF THE INVENTION

The present invention is based on an idea that the generation of the intermetallic compound and the P-enriched layer can be suppressed by diffusing the nickel layer when the thickness of the Ni layer occupied in the surface treatment plating layer is minimized, in the method of connecting the surface treatment plating layer to the external terminals using the solder joint.

An object of the present invention is to provide an electric joint structure capable of improving solder joint characteristics while having impact resistance by absorbing a nickel layer having a weak structure in an intermetallic compound during a reflow process.

Another object of the present invention is to provide a method for preparing an electric joint structure.

Another object of the present invention is to provide a printed circuit board including an electric joint structure.

According to an exemplary embodiment of the present invention, there is provided an electric joint structure, including: a joint, an intermetallic compound (IMC), and a solder layer, wherein the intermetallic compound (IMC) is generated from an electroless surface treatment plating layer including nickel plating coating of 1 μm or less.

The electroless surface treatment plating layer including the nickel plating coating may be an ENIG plating layer configured of electroless nickel plating coating and electroless gold plating coating or an ENEPIG plating layer configured of the electroless nickel plating coating, electroless palladium plating coating, and the electroless gold plating coating.

The intermetallic compound (IMC) may be made of Cu—Sn—Pd—Ni.

The intermetallic compound (IMC) may have a structure in which the content of Pd is 0.5 to 5 wt % and the content of Ni is 2 to 20 wt %.

The thickness of the intermetallic compound (IMC) may be 0.1 to 3 μm.

The electroless surface treatment plating layer and the solder layer of the electric joint structure may be connected to each other by solder joining.

The solder joining part may not substantially include a P-enriched layer.

The main component of the solder layer may be Sn.

According to another exemplary embodiment of the present invention, there is provided a method for preparing an electric joint structure including a joint, an intermetallic compound (IMC), and a solder layer, including: forming an electroless surface treatment plating layer including nickel on the joint; forming the solder layer on the electroless surface treatment plating layer; and forming the intermetallic compound (IMC) by a reflow process for solder joining.

A thickness of the electroless nickel plating coating of the electroless surface treatment plating layer may be 1 μm or less.

The intermetallic compound (IMC) may be made of Cu—Sn—Pd—Ni.

In the intermetallic compound (IMC), the content of Pd may be 0.5 to 5 wt % and the content of Ni may be 2 to 20 wt %.

The thickness of the intermetallic compound (IMC) may be 0.1 to 3 μm.

The solder joining part may not include a P-enriched layer.

The present invention may provide a printed circuit board including the electric joint structure.

### BRIEF DESCRIPTION OF THE DRAWINGS

FIG. 1 is a diagram showing a shape in which an intermetallic compound is generated when an electroless surface treatment plating layer including nickel is joined to a copper joint by a solder;

FIG. 2 is a diagram showing a shape in which the intermetallic compound is generated when a plating layer that does not include nickel is joined to a copper joint of the related art by a solder;

FIG. 3 shows a shape in which the intermetallic compound is generated when the solder according to an exemplary embodiment of the present invention is joined; and

FIG. 4 is a photograph of a cross section of an electric joint structure according to the exemplary embodiment of the present invention, which is observed by a scanning electron microscope.

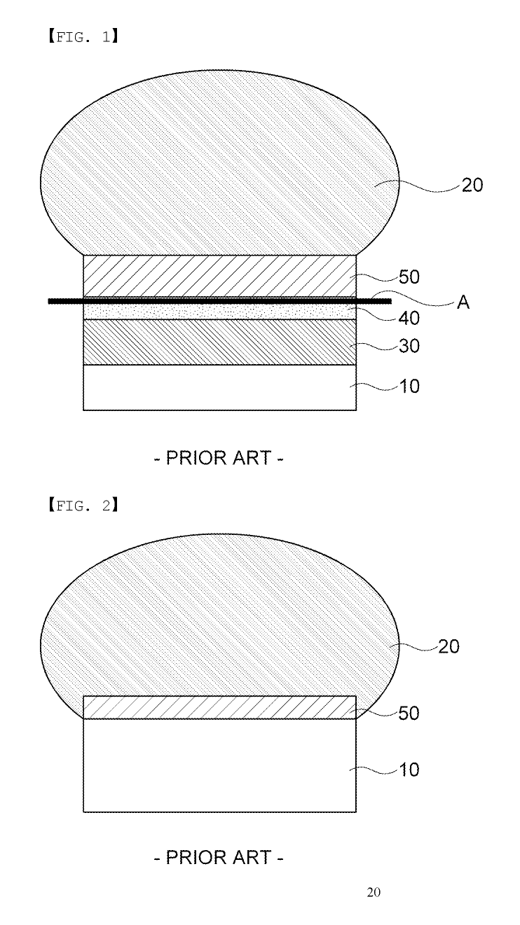

### DESCRIPTION OF THE PREFERRED EMBODIMENTS

Hereinafter, the present invention will be described in more detail.

Terms used in the present specification are for explaining the embodiments rather than limiting the present invention. Unless explicitly described to the contrary, a singular form includes a plural form in the present specification. The word “comprise” and variations such as “comprises” or “comprising,” will be understood to imply the inclusion of stated constituents, steps, operations and/or elements but not the exclusion of any other constituents, steps, operations and/or elements.

The exemplary embodiment of the present invention relates to an electric joint structure capable of improving solder joint reliability by absorbing an electroless nickel plating coating layer formed on a joint in an intermetallic compound layer during a reflow process.

The electric joint structure according to the exemplary embodiment of the present invention includes, a joint, an intermetallic compound (IMC) and a solder layer, wherein the intermetallic compound (IMC) may be generated from the electroless surface treatment plating layer including a nickel plating coating of 1 μm or less.

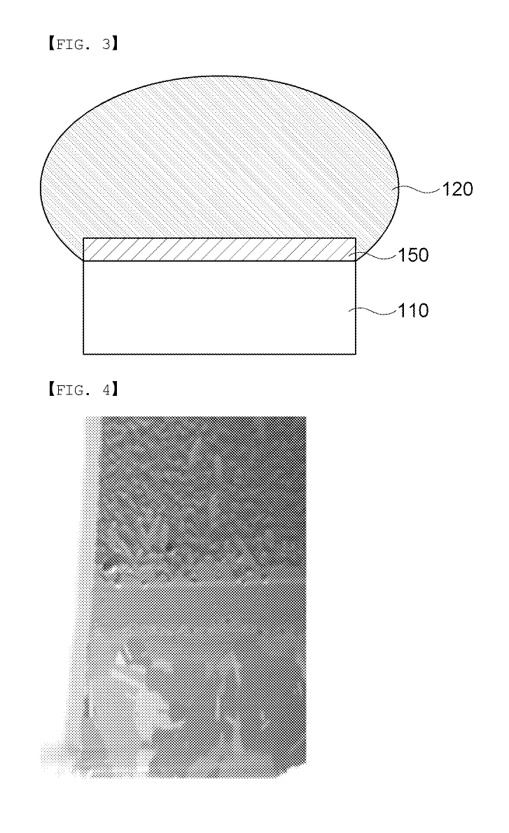

A structure of the electric joint structure according to the exemplary embodiment of the present invention is shown in FIG. 3. Referring to FIG. 3, the electric joint structure includes a copper joint 110, an intermetallic compound 150, and a solder layer 120.

The intermetallic compound 150 may be generated from the electroless surface treatment plating layer (not shown) including a nickel plating coating formed to treat a surface of the copper joint 110 during a reflow process.

The electroless surface treatment plating layer including the nickel plating coating may be an ENIG plating layer configured of electroless nickel plating coating and electroless gold plating coating or an ENEPIG plating layer configured of electroless nickel plating coating, electroless palladium plating coating, and electroless gold plating coating.

That is, the electroless surface treatment plating layer is formed before the reflow process is performed and then, the electroless gold plating coating included in the electroless surface treatment plating layer is absorbed in the solder layer 120 during the reflow process is performed, and Sn and some copper (Cu) metal from the copper joint 110 that are main component of the solder layer 120 are absorbed into nickel and palladium of the electroless surface treatment plating layer, thereby forming a new layer called the intermetallic compound 150.

During this process, the important fact is that the thickness of the nickel plating coating of the plating layer is very thin to a range of 1 μm or less, preferably, 0.02 to 0.5 μm even though the electroless surface treatment plating layer has any structure of the ENIG or ENEPIG. When the nickel plating coating is thick, some of the nickel layer remains rather than participating in the IMC reaction. In this case, other elements, in particular, phosphorus (P) is included in the nickel plating coating, thereby forming a P-enriched layer. Since the formed P-enriched layer has a negative effect in terms of the solder joint, the P-enriched layer, the Ni-Sn intermetallic compound, or the like, may be generated between the copper joint 110 and the solder layer 120 when the thickness of the nickel plating coating exceeds 1 μm, similar to the related art.

Therefore, the intermetallic compound (IMC) generated in the electric joint structure according to the exemplary embodiment of the present invention has a structure of Cu—Sn—Pd—Ni. The thickness of the intermetallic compound (IMC) may be 0.1 to 3 μm. When the thickness of the intermetallic compound (IMC) is below 0.1 μm, a concentration of Ni capable of suppressing voids of a Cu₃Sn layer is too low. In addition, when the thickness of the intermetallic compound (IMC) exceeds 3 μm, the IMC layer having strong brittleness is thick, thereby degrading the solder joint reliability.

The contents of Pd in the intermetallic compound (IMC) having the Cu—Sn—Pd—Ni structure may be 0.5 to 5 wt % and the contents of Ni may be 2 to 20 wt %.

In the electric joint structure according to the exemplary embodiment of the present invention, the electroless surface treatment plating layer is connected to the solder layer by the solder joint. In this case, the solder joining part does not substantially include the P-enriched layer.

As described above, this can obtain an effect of performing a control so as not to include the P-enriched layer at an interface joining part between the electroless surface treatment plating layer and the solder layer by maintaining the nickel layer in the electroless surface treatment plating layer at a minimum thickness.

In the electric joint structured according to the exemplary embodiment of the present invention, the main component of the solder layer may be Sn. The Sn that is the main component configuring the solder layer is partially absorbed into the intermetallic compound during the reflow process so as to be functioned as one component having the Cu—Sn—Pd—Ni structure that is the intermetallic compound.

A method for preparing an electric joint structure according to an exemplary embodiment of the present invention will be described in detail. First, the electroless surface treatment plating layer including nickel is formed on the joint. As the joint, copper may be used.

The electroless surface treatment plating layer includes the nickel metal coating, the electroless surface treatment plating layer may be the ENIG plating layer configured of the electroless nickel plating coating and the electroless gold plating coating or the ENEPIG plating layer configured of the electroless nickel plating coating, the electroless palladium plating coating, and the electroless gold plating coating.

The thickness of the nickel metal coating of the plating layer may be formed at 1 μm or less so as to maximally suppress the generation of the unwanted intermetallic compound.

In addition, the thickness of the palladium metal coating and the gold plating coating may each be formed at 0.02 to 0.3 μm and 0.02 to 0.5 μm in the plating layer.

Palladium and gold plating solutions configuring the electroless surface treatment plating layer according to the exemplary embodiment of the present invention may be used without being limited if they are generally used to those skilled in the art. In addition, any plating methods may be used without being particularly limited if they depend on a general level.

As described above, the electroless surface treatment plating layer configured of the electroless nickel plating coating and the electroless gold plating coating or the electroless surface treatment plating layer configured of the electroless nickel plating coating, the electroless palladium plating coating, and the electroless gold plating coating are sequentially formed on the copper joint and then, the solder layer is formed on the electroless surface treatment plating layer.

The solder layer uses a solder ball that is released in the market or may be formed by being applied to a separate solder forming materials, but any solder layer may be used.

Finally, the electric joint structure including the joint, the intermetallic compound (IMC), and the solder layer may be prepared by using a process of forming the intermetallic compound (IMC) by the reflow process for solder joining.

The reflow process may be performed based on the conditions used the joining method using the general solder method, but the exemplary embodiment of the present invention is not particularly limited.

The intermetallic compound (IMC) prepared by the reflow process may have the Cu—Sn—Pd—Ni structure. The contents of Pd in the intermetallic compound (IMC) having the Cu—Sn—Pd—Ni structure may be 0.5 to 5 wt % and the contents of Ni may be 2 to 20 wt %.

The thickness of the intermetallic compound (IMC) may be 0.1 to 3 μm.

In the electric joint structure according to the exemplary embodiment of the present invention, the electroless surface treatment plating layer is connected to the solder layer by the solder joint. In this case, the solder joining part does not substantially include the P-enriched layer.

In addition, the exemplary embodiment of the present invention does not include the intermetallic compound having different structures other than the Cu—Sn—Pd—Ni structure. If the method according to the related art has a structure having an interface between the Cu/Ni/Ni—Sn based intermetallic compound/solder or a structure having an interface of Cu/Cu—Sn based intermetallic compound/solder, the exemplary embodiment of the present invention has a structure having the structure of the Cu/Ni—Sn—Pd—Cu intermetallic compound/solder.

Therefore, the electric joint structure according to the exemplary embodiment of the present invention may have a joint structure capable of improving impact resistance and increasing the solderability to the existing Ni/Au layer level since the electric joint structure has the Ni layer before the reflow process is performed.

The exemplary embodiment of the present invention may provide the printed circuit board including the prepared electric joint structure.

However, examples of the present invention will be described below in more detail. These examples only describe the present invention, but the present invention is not limited thereto.

Preparation of Test Substrate

A test substrate was prepared by forming an etching resist that is formed by machining holes a copper clad laminate and performing a through hole and forming a pad for a solder ball joint having φ600 μm in a plating resist used as a solder resist so as not to precipitate plating at an unnecessary position by removing unnecessary copper by etching.

Pre-Treatment Process

The pre-treatment was performed by performing the surface treatment on the pad for the solder ball joint of the prepared test substrate using the following process. The test substrate was immersed in a degreasing liquid ACL-007 (available from UYEMURA Co. brand name) at 50° C. for 3 minutes, washed for 2 minutes, and then, immersed and etched in 100g/L of sodium perphosphate solution for 1 minute. Thereafter, the test substrate was washed for two minutes and immersed in 10% of sulfuric acid for 1 minute, subjected to acid activation, and then washed for 2 minutes. Next, the test substrate was immersed and treated in a plating activation treating liquid, that is, Accemarta MSR-28 (available from UYEMURA Co. brand name) at 35° C. for 3 minutes and then, washed for 2 minutes.

### EXAMPLE

### 1) Electroless Ni Plating

The electroless nickel plating coating having a thickness of 0.1 μm was obtained by immersing the substrate subjected to the pre-treatment process in the electroless Ni plating solution (products available from TOP NICORON LPH-LF: OKUNO Co.) in a medium Ni—P type containing 6 to 9 wt % of phosphorus included in the plating coating at 75° C. for 1 minute and then, washing it for two minutes.

### 2) Electroless Pd Plating

The electroless palladium plating coating having a thickness of 0.1 μm was obtained by immersing the substrate to which the electroless Ni is plated in the electroless Pd plating solution, that is, XTP (P=3 wt %, products available from UYEMURA) at 50° C. for 10 minutes and washing it for two minutes.

### 3) Electroless Au Plating

The substrate to which the Pd is applied was immersed in the electroless gold plating solution, that is, GoBright TSB-72 (product available from UYEMURA Co.) at 80° C. for 5 minutes and washed for 2 minutes, and then, dried at 150° C. for 5 minutes by a blowing drier. The electroless nickel/palladium/gold plating layer on which the electroless gold plating coating having a thickness of 0.1 μm is formed was obtained.

### 4) Solder Joint

A Pb free solder ball (SAC305, φ760 μm: product available from Senju Metal Industry Co., Ltd.) using the Sn as main component was connected to the terminal for the plated substrate solder ball connection in a reflow furnace. After the connection, the prepared substrate is heat-treated at 150° C. for 100 hours.

### Experimental Example

The cross section of the substrate subjected to the reflow process was observed by the scanning electron microscope and the observed results were shown in FIG. 4.

Next, it can be appreciated from FIG. 4 that the electric joint structure according to the exemplary embodiment of the present invention is provided with the copper joint, the intermetallic compound having the Cu—Sn—Pd—Ni, and the solder layer.

The structure of the intermetallic compound according to the exemplary embodiment of the present invention does not include the phosphorous component and does not include the Ni—Sn based intermetallic compound that may provide the cause of fracture of the related art. The results are effects obtained by minimizing the thickness of the nickel layer of the electroless surface treatment plating layer plated to the copper joint, which suppress the generation of the unwanted intermetallic compound to improve the impact resistance of the substrate and secure the reliability at the time of the solder joint.

As set forth above, the electric joint structure having the intermetallic compound structure can have the joint structure capable of improving the impact resistance by suppressing the generation of the Ni—Sn based intermetallic compound and the P-enriched layer at the solder joint interface during the reflow process and improving the solderability including the Ni layer before the reflow process.

What is claimed is:

1. An electric joint structure, comprising:
a joint, an intermetallic compound (IMC), and a solder layer,
wherein the intermetallic compound (IMC) is generated from an electroless surface treatment plating layer including nickel plating coating of 1 μm or less.

2. The electric joint structure according to claim 1, wherein the electroless surface treatment plating layer including the nickel plating coating is an ENIG plating layer configured of electroless nickel plating coating and electroless gold plating coating or an ENEPIG plating layer configured of the electroless nickel plating coating, electroless palladium plating coating, and the electroless gold plating coating.

3. The electric joint structure according to claim 1, wherein the intermetallic compound (IMC) is made of Cu—Sn—Pd—Ni.

4. The electric joint structure according to claim 1, wherein the intermetallic compound (IMC) has a structure in which the content of Pd is 0.5 to 5 wt % and the content of Ni is 2 to 20 wt %.

5. The electric joint structure according to claim 1, wherein the thickness of the intermetallic compound (IMC) is 0.1 to 3 μm.

6. The electric joint structure according to claim 1, wherein the electroless surface treatment plating layer and the solder layer of the electric joint structure are connected to each other by solder joining.

7. The electric joint structure according to claim 6, wherein the solder joining part does not include a P-enriched layer.

8. The electric joint structure according to claim 1, wherein the main component of the solder layer is Sn.

9. A method for preparing an electric joint structure including a joint, an intermetallic compound (IMC), and a solder layer, comprising:
forming an electroless surface treatment plating layer including nickel on the joint;
forming the solder layer on the electroless surface treatment plating layer; and
forming the intermetallic compound (IMC) by a reflow process for solder joining.

10. The method according to claim 9, wherein a thickness of the electroless nickel plating coating of the electroless surface treatment plating layer is 1 μm or less.

11. The method according to claim 9, wherein the intermetallic compound (IMC) is made of Cu—Sn—Pd—Ni.

12. The method according to claim 11, wherein in the intermetallic compound (IMC), the content of Pd is 0.5 to 5 wt % and the content of Ni is 2 to 20 wt %.

13. The method according to claim 9, wherein the thickness of the intermetallic compound (IMC) is 0.1 to 3 μm.

14. The method according to claim 9, wherein the solder joining part does not include a P-enriched layer.

15. A printed circuit board including the electric joint structure according to claim 1.
